(19) United States
(12) Patent Application Publication
(10) Pub. No.: US 2018/0135182 A1
(43) Pub. Date: May 17, 2018

(54) GRAPHITE BOAT TRANSMISSION MECHANISM USED IN PECVD DEVICE

(71) Applicant: S.C New Energy Technology Corporation, Shenzhen (CN)

(72) Inventors: Yuenan Xiao, SHENZHEN (CN); Yong Zhang, SHENZHEN (CN)

(21) Appl. No.: 15/867,970

(22) Filed: Jan. 11, 2018

Related U.S. Application Data
(63) Continuation of application No. PCT/CN2017/098530, filed on Aug. 22, 2017.

(30) Foreign Application Priority Data
Aug. 25, 2016 (CN) 201620938505.7

(51) Int. Cl. C23C 16/50; C23C 16/52; B25J 18/02

(52) U.S. Cl. CPC C23C 16/50; B25J 18/025; C23C 16/52

(57) ABSTRACT

A graphite boat transmission mechanism used in a PECVD device includes a stand column and a boat pushing mechanism fixed at opposite sides in the PECVD device and a side boat leaving mechanism fixed at the bottom of the PECVD device. Separated temporary storage sections are fixed on the stand column from top to bottom, temporary storage sections have a temporary storage section center line in a vertical direction, an SIC oar horizontally stretches from the boat pushing mechanism, a lift channel section is arranged between the SIC oar and the temporary storage sections, the stand column has a manipulator moving up and down along the stand column, the manipulator grabs the graphite boat on the SIC oar and then transmits the graphite boat to the lift channel, and the side boat leaving mechanism is fixed at the bottom of the PECVD device and located below the temporary storage sections.

### CROSS-REFERENCE TO RELATED PATENT APPLICATION

This application is a continuation application of International Patent Application No. PCT/CN2017/098530, filed on Aug. 22, 2017, which itself claims priority to Chinese Patent Application No. CN201620938505.7 filed in China on Aug. 25, 2016. The disclosures of the above applications are incorporated herein in their entireties by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to the production equipment in the photovoltaic industry, and more particularly, to a graphite boat transmission mechanism used in a PECVD device.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The PECVD device is internally provided with a set of transmission mechanism, and the function of the mechanism is to realize the transmission of a graphite boat on all positions in up and down, and front and back directions in the PECVD device. The up and down positions of the transmission are the positions of an SIC oar and all temporary storage sections, and the positions of the transmission in front and back directions are: the temporary storage sections, a lift channel section and an SIC oar section of a boat pushing mechanism in sequence. After a manipulator takes and places the graphite boat in the temporary storage sections or on the SIC oar, it needs to be sent back to the lift channel section firstly to go up or down to a required height, and then carry out next movement.

As shown in FIG. 1, in the existing design, the position of the side boat leaving mechanism 6 is located below the lift channel section 5 of the manipulator. Assuming that the graphite boat 8 transmitted on the side boat leaving mechanism 6 has reached the grabbing position of the manipulator, or is operated in the region, and the manipulator transmits the graphite boat 8 grabbed from the SIC oar 4 and returns back to the lift channel section 5, if the position of the SIC oar 4 for taking and placing the boat is relatively high, the manipulator cannot collide with the graphite boat 8 transmitted on the side boat leaving mechanism 6 when the manipulator grabs the graphite boat 8 on the SIC oar 4 and returns back to the lift channel section 5. As shown in FIG. 2, if the position of the SIC oar 4 for taking and placing the boat is relatively low or the height is reduced, the manipulator can collide with the graphite boat 8 transmitted on the side boat leaving mechanism 6 when the manipulator grabs the graphite boat 8 on the SIC oar 4 and then returns back to the lift channel section 5, which causes damage to the graphite boat.

### SUMMARY

In order to solve the problems in the prior art, the present invention provides a graphite boat transmission mechanism used in a PECVD device. When the position of the SIC oar for taking and placing the boat is relatively low, the manipulator cannot collide with the graphite boat transmitted on the side boat leaving mechanism when the manipulator grabs the graphite boat on the SIC oar and then transmits the graphite boat to the lift channel section.

The technical solution of the present invention is that: A graphite boat transmission mechanism used in a PECVD device comprises a stand column fixed at one side in the PECVD device, a boat pushing mechanism fixed at the other side in the PECVD device and a side boat leaving mechanism fixed at the bottom of the PECVD device, wherein a plurality of separated temporary storage sections are fixed on the stand column from top to bottom, the temporary storage sections have a temporary storage section center line in a vertical direction, an SIC oar horizontally stretches from the boat pushing mechanism, a lift channel section is arranged between the SIC oar and the temporary storage sections, the stand column is further provided with a manipulator moving up and down along the stand column, and the side boat leaving mechanism is fixed at the bottom of the PECVD device and located below the temporary storage sections.

The manipulator comprises a horizontal arm and a grip, one end of the horizontal arm is installed on the stand column, the grip is installed on the other end of the horizontal arm, and the grip moves left and right along the horizontal arm.

The side boat leaving mechanism is fixed at the bottom of the PECVD device through a fixing seat, the fixing seat comprises a connecting plate and at least two separated annular frames arranged at the same side as the connecting plate; the bottom of the PECVD device is provided with a beam, and the annular frame is sleeved on the beam and connected to the beam through a screw.

According to the graphite boat transmission mechanism used in a PECVD device provided by the present invention, the side boat leaving mechanism is fixed at the bottom of the PECVD device and located below the temporary storage sections, when the position of taking and placing the boat of the SIC oar is relatively low, the manipulator cannot collide with the graphite boat transmitted on the side boat leaving mechanism when the manipulator grabs the graphite boat on the SIC oar and then transmits the graphite boat to the lift channel. Moreover, when the position of taking and placing the boat of the SIC oar is relatively low, the overall height of the PECVD device can also be reduced, so that the adaptive performance of the PECVD device can be greatly increased.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a schematic diagram of transmitting a graphite boat when the position of an SIC oar for taking and placing the boat is relatively high in the prior art;

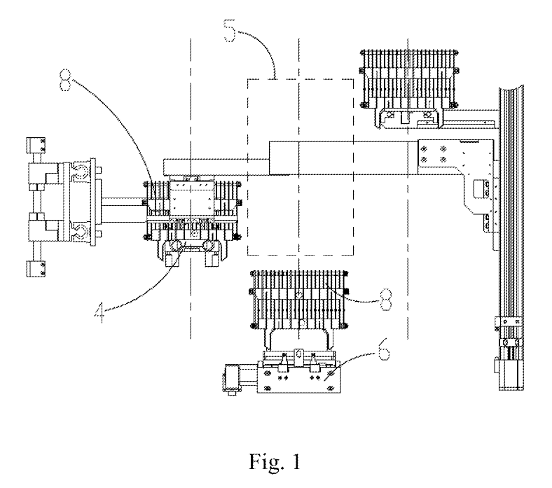

FIG. 2 is a schematic diagram of transmitting the graphite boat when the position of the SIC oar for taking and placing the boat is relatively low in the prior art;

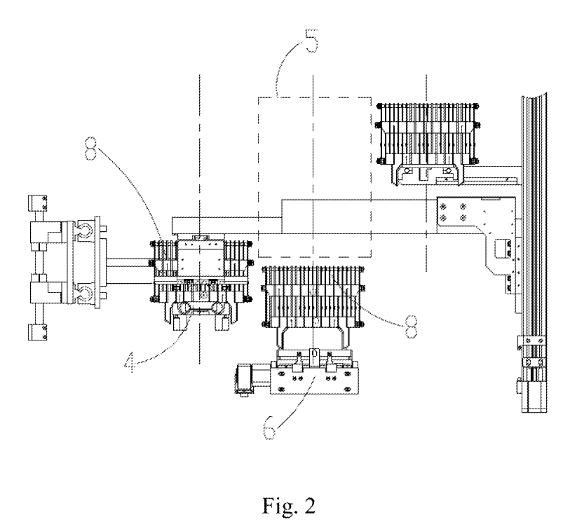

FIG. 3 is a schematic diagram of a graphite boat transmission mechanism installed in a PECVD device according to the present invention;

FIG. 4 is a schematic diagram of the graphite boat transmission mechanism according to the present invention;

FIG. 5 is a structure diagram of a fixing seat in the present invention;

FIG. 6 is a bottom structure diagram of the PECVD device in the present invention;

FIG. 7 is a schematic diagram of connecting the fixing seat with a beam; and

FIG. 8 is an enlarged diagram of part A in FIG. 6.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

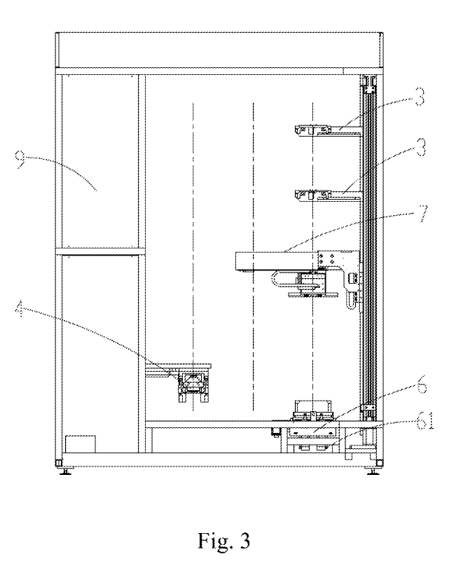

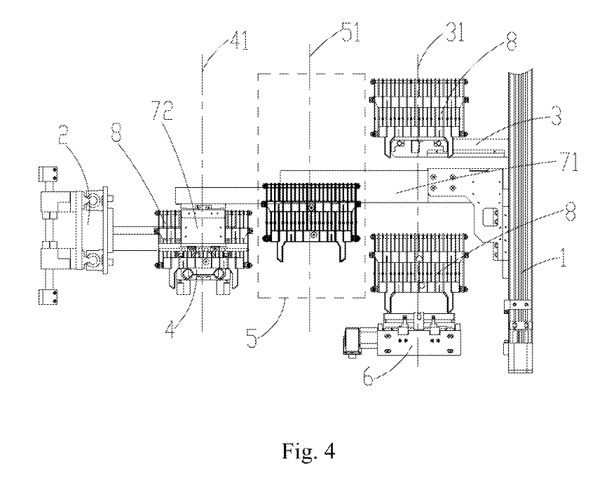

As shown in FIG. 3 and FIG. 4, the present invention provides a graphite boat transmission mechanism used in a PECVD device, which comprises a vertically-upward stand column 1 fixed on one side in the PECVD device 9, a boat pushing mechanism 2 fixed on the other side in the PECVD device 9 and a side boat leaving mechanism 6 fixed at the bottom of the PECVD device 9. A plurality of separated temporary storage sections 3 are fixed on the stand column 1 from top to bottom, the temporary storage sections 3 are used for placing the graphite boat processed or to be processed, and the temporary storage sections 3 have a temporary storage section center line 31 in a vertical direction. The stand column 1 is further provided with a manipulator 7 moving up and down along the stand column 1, the manipulator 7 comprises a horizontal arm 71 and a grip 72, one end of the horizontal arm 71 is installed on the stand column 1, the grip 72 is installed on the other end of the horizontal arm 71, the grip 72 is used for grabbing the graphite boat, and the grip 72 moves left and right along the horizontal arm 71, so as to transmit the graphite boat.

An SIC oar 4 horizontally stretches from the boat pushing mechanism 2, the SIC oar 4 is used for taking out/feeding the graphite boat processed/to be processed from/into a graphite tube, and the height of the position of the SIC oar 4 for taking the boat adjusted by the height of the position on the PECVD device where the boat pushing mechanism is installed on. The SIC oar 4 has an SIC oar center line 41 in a vertical direction.

A lift channel section 5 is arranged between the SIC oar 4 and the temporary storage sections 3, the lift channel section 5 is an operation area where the manipulator goes up or down, and after the manipulator grabs the graphite boat 8 on the SIC oar 4, the manipulator needs to be sent back to the lift channel section 5 firstly, and then carry out next movement after the manipulator goes up or down to the required height in the lift channel section 5. The lift channel section 5 has a lift channel section center line 51 in a vertical direction.

In the embodiment, the side boat pushing mechanism 6 is fixed at the bottom of the PECVD device 9 and located below the temporary storage sections 3. Thus, since the side boat pushing mechanism 6 is at the right side of the lift channel section, whether the position of the SIC oar 4 for taking the boat is relatively high or low, the grip 72 cannot collide with the graphite boat 8 transmitted on the side boat leaving mechanism 6 in the process that the grip 72 grabs the graphite boat 8 on the SIC oar 4 and then transmits the graphite boat 8 to the lift channel section.

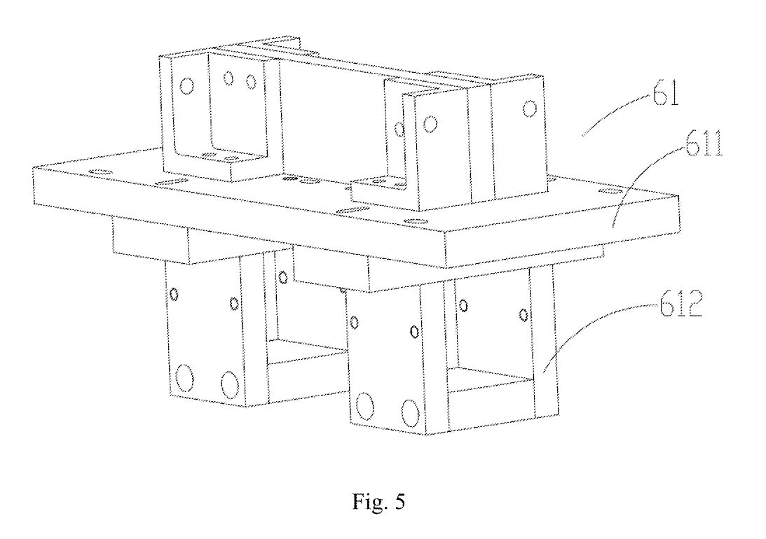

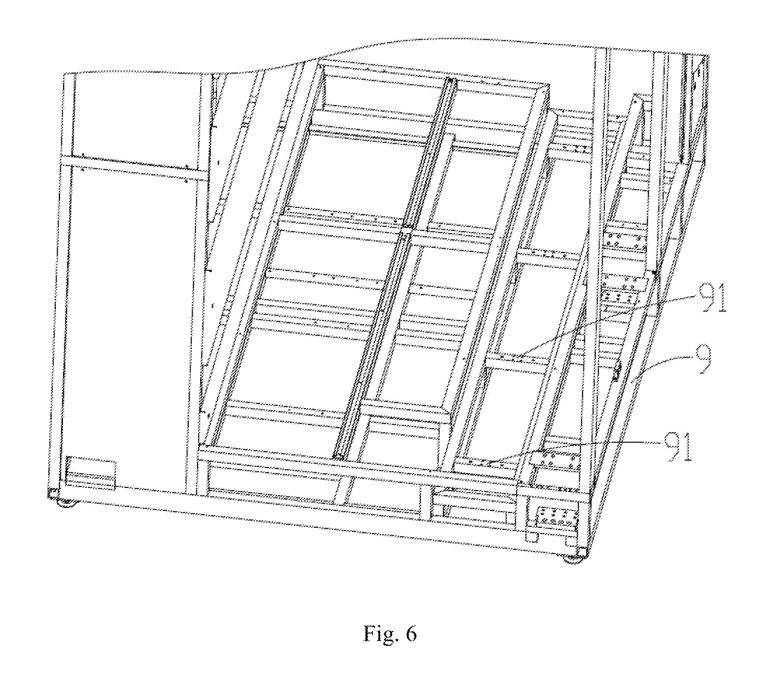

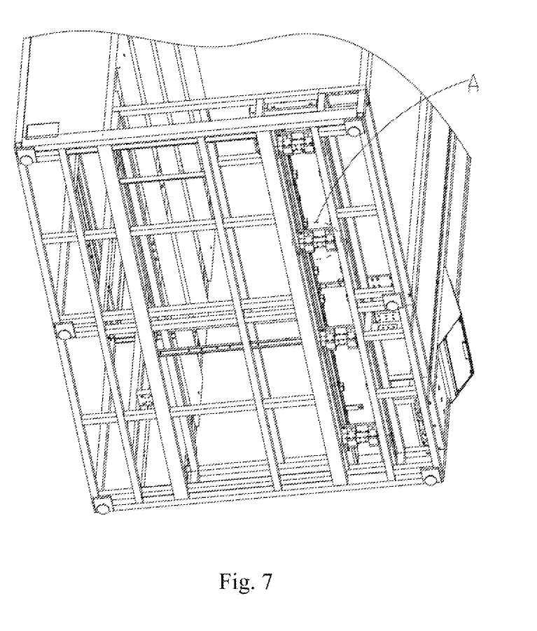

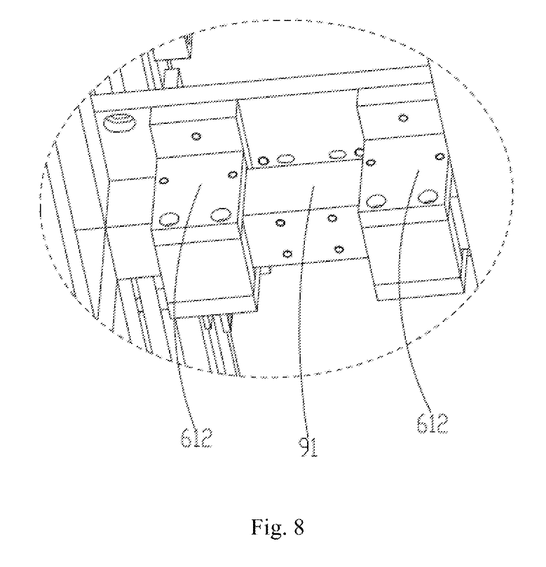

As shown in FIG. 4, the side boat leaving mechanism 6 is fixed at the bottom of the PECVD device through a fixing seat 61. As shown in FIG. 5, the fixing seat 61 comprises a connecting plate 611 and at least two separated annular frames 612 arranged at the same side as the connecting plate 611. As shown in FIG. 6, the bottom of the PECVD device is provided with a beam 91, and the beam 91 is welded at the bottom of the PECVD device 9. As shown in FIG. 7 and FIG. 8, the annular frame 612 is sleeved on the beam 91 and connected to the beam through a screw.

According to the graphite boat transmission mechanism used in a PECVD device provided by the present invention, the side boat leaving mechanism is fixed at the bottom of the PECVD device and located below the temporary storage sections, and the manipulator cannot collide with the graphite boat transmitted on the side boat leaving mechanism when the manipulator grabs the graphite boat on the SIC oar and then transmits the graphite boat to the lift channel section. Moreover, the height of the position of the SIC oar for taking the boat decides the overall height of the PECVD device to a large extent. Therefore, under the condition of the same quantity of the tubes of the PECVD device, when the position of the SIC oar for taking the boat is relatively low, the overall height of the PECVD device can also be reduced, so that the adaptive performance of the PECVD device can be greatly increased.

The description above is only the preferable embodiment of the present invention, and is not used to limit the present invention. Any modification, equal replacement and improvement made in the spirit and principle of the present invention shall fall in the protection scope of the present invention.

What is claimed is:

1. A graphite boat transmission mechanism used in a PECVD device, comprising a stand column (1) fixed at one side in the PECVD device (9), a boat pushing mechanism (2) fixed at the other side in the PECVD device and a side boat leaving mechanism (6) fixed at a bottom of the PECVD device, wherein a plurality of separated temporary storage sections (3) are fixed on the stand column from top to bottom, the temporary storage sections have a temporary storage section center line (31) in a vertical direction, an SIC oar (4) horizontally stretches from the boat pushing mechanism, a lift channel section (5) is arranged between the SIC oar and the temporary storage sections, the stand column is further provided with a manipulator (7) moving up and down along the stand column, and the side boat leaving mechanism is fixed at the bottom of the PECVD device and located below the temporary storage sections.

2. The graphite boat transmission mechanism according to claim 1, wherein the manipulator (7) comprises a horizontal arm (71) and a grip (72), one end of the horizontal arm is installed on the stand column (1), the grip is installed on the other end of the horizontal arm, and the grip moves left and right along the horizontal arm.

3. The graphite boat transmission mechanism according to claim 2, wherein the side boat leaving mechanism (6) is fixed at the bottom of the PECVD device (9) through a fixing seat (61), the fixing seat comprises a connecting plate (611) and at least two separated annular frames (612) arranged at the same side as the connecting plate; the bottom of the PECVD device is provided with a beam (91), the beam is welded at the bottom of the PECVD device, and the annular frames are covered on the beam and are connected to the beam through a screw.
